(19) United States
(12) Patent Application Publication
(10) Pub. No.: US 2021/0238739 A1
(43) Pub. Date: Aug. 5, 2021

(54) PROCESSING APPARATUS AND PROCESSING METHOD

(71) Applicant: KIOXIA CORPORATION, Tokyo (JP)

(72) Inventors: Ryu KOMATSU, Atsugi Kanagawa (JP); Takeharu MOTOKAWA, Zushi Kanagawa (JP); Noriko SAKURAI, Yokohama Kanagawa (JP); Hideaki SAKURAI, Kawasaki Kanagawa (JP)

(21) Appl. No.: 17/009,388

(22) Filed: Sep. 1, 2020

(30) Foreign Application Priority Data
Feb. 4, 2020 (JP) 2020-017490

(51) Int. Cl. C23C 16/44; H01J 37/32; C23C 16/50; G03F 7/00

(52) U.S. Cl. CPC C23C 16/4402; H01J 37/3244; H01J 37/32724; H01L 21/027; C23C 16/50; G03F 7/0002; H01J 37/32651

(57) ABSTRACT

According to one embodiment, a processing apparatus includes a chamber, a first gas introduction port that introduces a first gas into the chamber, a first gas discharge port that discharges the first gas from the chamber, and a stage that supports a processing object in the chamber. The processing apparatus has a plasma generating section with an electrode to generate a plasma in the chamber. The processing apparatus includes a shield at a first position that is between the plasma generating section and the stage. The shield is light transmissive, but blocks radicals and ions generated with plasma. In some examples, the shield may be moveable from the first position to another position that is not between the plasma generating section and the stage.

### CROSS-REFERENCE TO RELATED APPLICATION(S)

This application is based upon and claims the benefit of priority from Japanese Patent Application No. 2020-017490, filed Feb. 4, 2020, the entire contents of which are incorporated herein by reference.

### FIELD

Embodiments described herein relate generally to a processing apparatus and a processing method.

### BACKGROUND

As a lithography process for the manufacturing of a semiconductor device, nanoimprint lithography has been proposed as a pattern transfer method which takes the place of photolithography. In nanoimprint lithography, a patterned template is directly pressed against a substrate coated with a liquid organic material to transfer the pattern of the template to the substrate.

### BRIEF DESCRIPTION OF THE DRAWINGS

FIG. 1 is a cross-sectional view depicting a processing apparatus according to a first embodiment.

FIG. 2 is a top view depicting a template according to a first embodiment.

FIGS. 3A through 3C are cross-sectional views depicting templates according to a first embodiment.

FIG. 4 is a diagram illustrating aspects of a processing method according to a first embodiment.

FIG. 5 is a graph of a plasma emission spectrum of N₂ gas.

FIGS. 6A and 6B are diagrams illustrating aspects of a processing method according to a first embodiment performed on fine structures of a template depicted in FIG. 3C.

FIGS. 7A and 7B are cross-sectional views depicting a processing apparatus according to a second embodiment.

FIG. 8 is a cross-sectional view depicting a processing apparatus according to a third embodiment.

FIGS. 9A through 9E are diagrams illustrating aspects of a method for carrying in a template according to a third embodiment.

FIGS. 10A and 10B are diagrams illustrating aspects of a processing method according to a fourth embodiment.

### DETAILED DESCRIPTION

In general, according to one embodiment, a processing apparatus includes a chamber, a first gas introduction port that introduces a first gas into the chamber, a first gas discharge port that discharges the first gas from the chamber, and a stage that supports a processing object in the chamber. The processing apparatus has a plasma generating section with an electrode. The plasma generating section is configured to generate a plasma in the chamber. The processing apparatus includes a shield at a first position that is between the plasma generating section and the stage. The shield is light transmissive.

Certain example embodiments of the present disclosure will now be described with reference to the drawings. In the drawings and in the following description, the same reference symbols are used for the same or substantially similar components or elements. The drawings are schematic; thus, the size ratio between components or elements, etc. are not necessarily to scale.

### First Embodiment

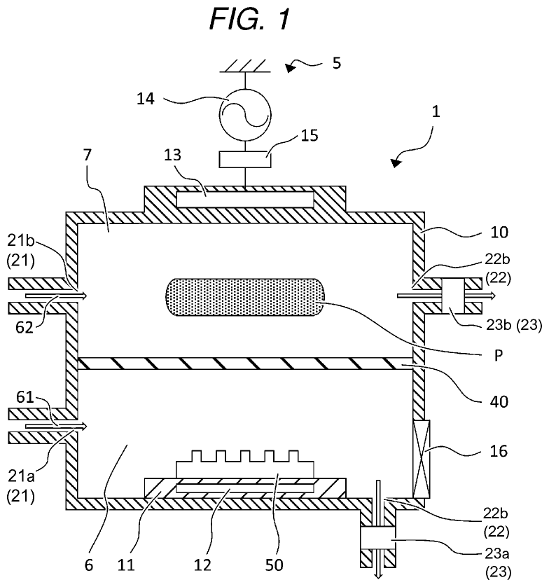

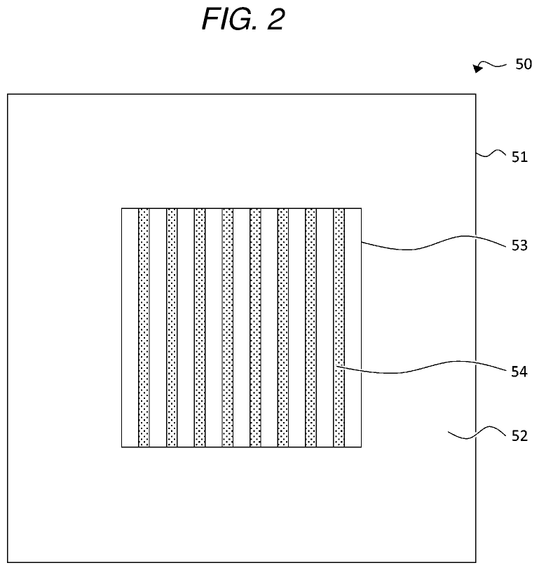

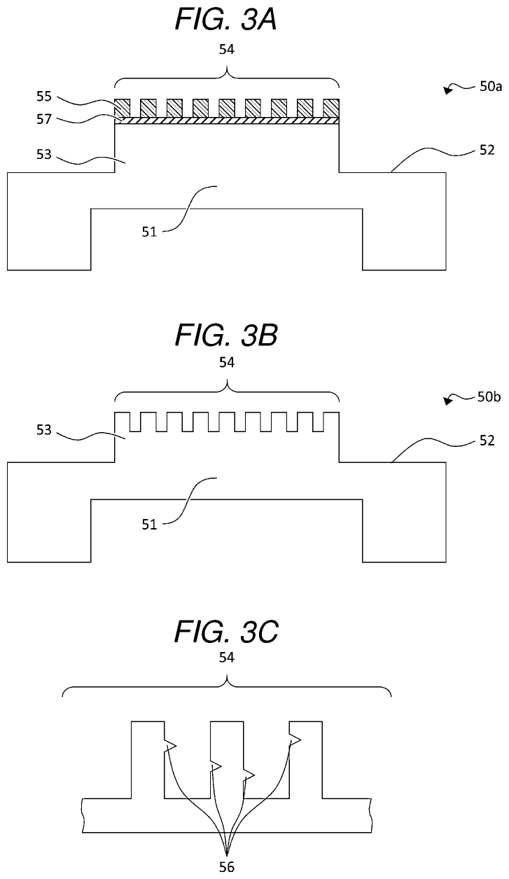

A processing apparatus and a processing method according to a first embodiment will be described with reference to FIGS. 1 through 6. FIG. 1 is a cross-sectional view showing the configuration of the processing apparatus according to this embodiment. FIG. 2 is a top view showing a template 50 according to this embodiment. FIGS. 3A through 3C are cross-sectional views showing the template 50 according to this embodiment.

The processing apparatus of the first embodiment will be described first. The processing apparatus of this embodiment is, for example, an apparatus for smoothing a pattern already formed on a substrate (or processing object). While the following description illustrates the use of an imprinting template as a processing object, it is also possible to use a patterned semiconductor substrate (such as a semiconductor wafer or the like).

As shown in FIG. 1, the processing apparatus 1 includes a chamber 10 and a stage 11. A heater 12 is provided for adjusting the temperature of a processing object (e.g., an imprinting template 50 or a template 50) in the chamber 10. The stage 11 can support the imprinting template 50. The heater 12 heats the template 50 supported on the stage 11 to adjust the temperature of the template.

As shown in FIG. 1, the processing apparatus 1 includes a plasma generating section 5. The plasma generating section 5 includes an electrode 13, a power source 14 and a matching box (may also be referred to as an impedance matching unit, a matching network, or the like). The electrode 13 is provided above the stage 11 in the chamber 10. The power source 14 is electrically connected by wiring to the matching box 15. The matching box 15 is electrically connected by wiring to the electrode 13. The plasma generating section 5 causes a high-frequency discharge in the chamber 10 and generates a plasma P.

A shield 40 is provided in the chamber 10 in the space between the stage 11 and the electrode 13. The chamber 10 is thus divided by the shield 40 into a processing division 6, which contains the stage 11, and a light source division 7, which contains the plasma generating section 5. The shield 40 comprises, for example, glass, sapphire, calcium fluoride, magnesium fluoride, polycarbonate, or an acrylic resin. The shield 40 shields the processing division 6 from ions, radicals, etc. generated along with the plasma in the light source division 7.

Gas introduction ports 21 (21a, 21b) and gas discharge portions 22 (22a, 22b) are provided in the chamber 10. The gas introduction port 21a and the gas discharge portion 22a are provided in the processing division 6, while the gas introduction port 21b and the gas discharge portion 22b are provided in the light source division 7. The gas discharge portions 22 are provided with pressure regulators 23 (23a, 23b) for regulating the amount of exhaust gas. The gas introduction ports 21 may be provided with flow regulators for regulating the flow rate of an incoming gas. The gas introduction port 21a, provided in the processing division 6, introduces a processing gas 61 into the processing division 6. The gas introduction port 21b, provided in the light source division 7, introduces a light source gas 62 into the light source division 7.

An opening is provided in the side wall of the processing division 6 of the chamber 10, and a gate valve 16 is provided such that it closes the opening.

The template 50 as a processing object is carried through the opening into the processing division 6, and carried through the opening out of the processing division 6. The processing apparatus 1 also includes a conveyance section or the like that places the template 50 on the stage 11.

As shown in FIG. 2, the template 50 is a processed quadrangular substrate 51. The substrate 51 is, for example, composed mainly of quartz (or other transparent material). An elevated portion 53 is provided in and around the center of the main surface 52 of the substrate 51. The elevated portion 53 is formed of the same material as that of the substrate 51. The elevated portion 53 is a mesa-like structure projecting from the main surface 52. The elevated portion 53 may be referred to as a mesa structure or, more simply, a mesa in some contexts.

The elevated portion 53 has a patterned surface 54 having a three-dimensional pattern formed therein or thereon as a topographic relief structure or the like. For example, the three-dimensional pattern may comprise grooves, trenches, recesses, holes, or the like etched into the patterning surface and/or protrusions, tiers, pillars, or the like formed on the patterning surface. While FIG. 2 illustrates the template 50 having a line-and-space structure as an example of a three-dimensional pattern, the three-dimensional pattern of the template 50 is not limited to a line-and-space structure.

FIGS. 3A through 3C show an example of cross-sectional structures of templates 50 according to this embodiment.

The template 50a shown in FIG. 3A has the patterned surface 54 in which the three-dimensional pattern is formed in a resin layer 55. The resin layer 55 is provided on a chromium layer 57 formed on the elevated portion 53. The resin layer 55 is formed of, for example, a resist composed mainly of a novolac resin.

The template 50b of FIG. 3B, the three-dimensional pattern is formed directly in the elevated portion 53. The template 50b is produced, for example, by etching using the resin layer 55 of the template 50a as a mask.

As shown in FIG. 3C, certain fine structures 56, which are three-dimensional portions finer than the main three-dimensional pattern, exist in the patterned surface 54. The fine structures 56 may be referred to as pattern roughness, sidewall roughness, sub-pattern dimension features. The patterned surface 54 of the template 50 of this embodiment may have either the configuration of the template 50a or the configuration of the template 50b, but, in either case, fine structures 56 are present. The processing associated with removing and/or reducing such fine structures 56 is referred to as smoothing or leveling in this context.

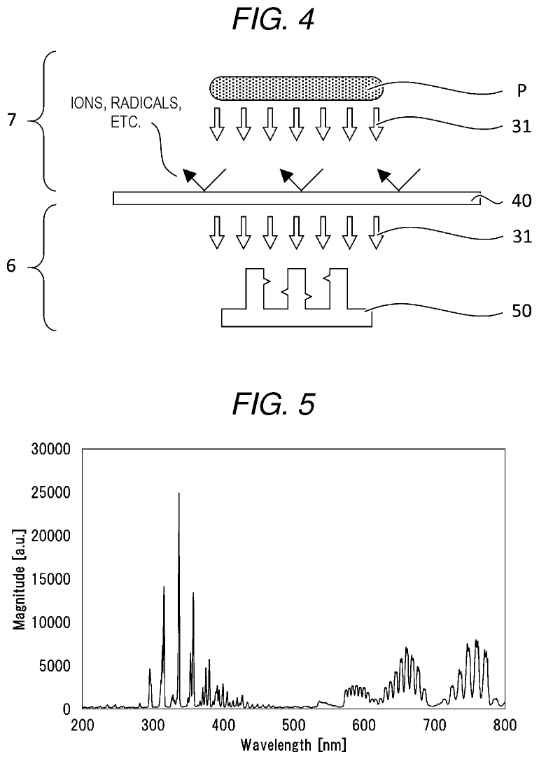

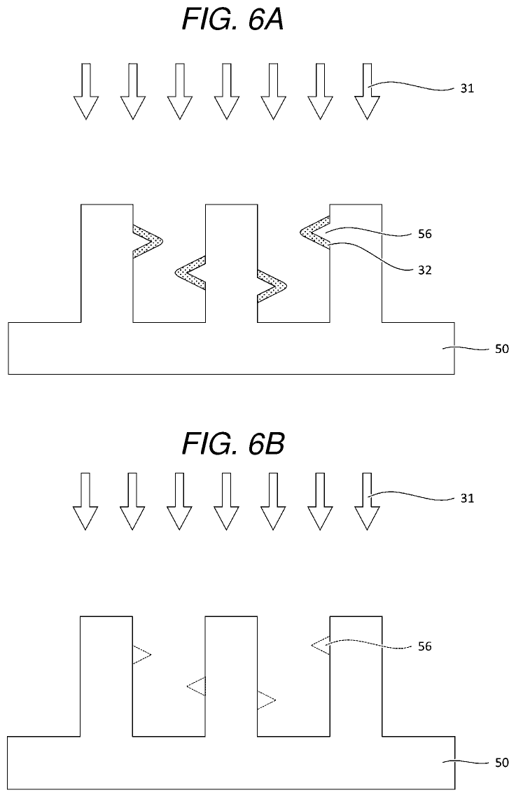

A method for processing the template 50 using the processing apparatus 1 will now be described with reference to FIG. 1 and FIGS. 4 through 6. FIG. 4 is a diagram illustrating a processing method according to this embodiment. FIG. 5 shows a plasma emission spectrum of N₂ gas which is a light source gas. FIGS. 6A and 6B are diagrams schematically illustrating the processing method for the template 50 performed in the processing division 6.

First, the gate valve 16 of the processing apparatus 1, shown in FIG. 1, is opened, and the template 50 is placed in the chamber 10 on the stage 11 by the conveyance section or the like. The template 50 is placed with the patterned surface 54 facing the electrode 13 in the chamber 10. After the placement of the template 50, the gate valve 16 is closed.

Subsequently, a processing gas 61 is introduced into the processing division 6 of the chamber 10. A light source gas 62 is introduced into the light source division 7. Examples of the processing gas 61 include reactive gases such as oxygen (O₂), ozone (O₃), nitrous oxide (N₂O), carbon monoxide (CO), carbon dioxide (CO₂), fluorine (F₂), nitrogen trifluoride (NF₃), nitrogen tetrafluoride (NF₄), hexafluoro-1,3-butadiene (C₄F₆), octafluorocyclobutane (C₄F₈), fluoroform (CHF₃), difluoromethane (CH₂F₂), sulfur hexafluoride (SF₆), chlorine (Cl₂), boron trichloride (BCl₃), hydrogen chloride (HCl), and hydrogen bromide (HBr). A mixed gas comprising such a reactive gas and an inert gas, such as nitrogen (N₂), argon (Ar) or helium (He) may also be used. The reactive gas may be appropriately selected depending on the material and thickness of the patterned surface 54 of the template 50, etc. The use of the reactive gas enables etching of raised portions of the fine structures 56 of the template 50. A gas such as N₂, O₂, Ar or He, for example, can be used as the light source gas 62. The light source gas 62 may be appropriately selected depending on the dissociation energy of the reactive gas used for the processing gas 61, etc., as will be described below. The pressure in the processing division 6 and the pressure in the light source division 7 are regulated by the pressure regulators 23. The pressure in the processing division 6 is regulated, for example, to about 1 Pa to about atmospheric pressure. The pressure in the light source division 7 is regulated, for example, to about 0.1 Pa to about 100 Pa.

Thereafter, the plasma generating section 5 generates a plasma P in the light source division 7. The plasma P may be generated, for example, by an inductively-coupled plasma method or an electron cyclotron resonance discharge method. As shown in FIG. 4, when the plasma P is generated in the light source division 7, the template 50 in the processing division 6 is irradiated with plasma light 31 that has passed through the shield 40. In the light source division 7, ions, radicals, etc. are generated along with the plasma P. However, movement of the ions and radicals to the processing division 6 is blocked by the shield 40. Thus, the template 50 in the processing division 6 can be prevented from being etched by the ions and radicals generated in the light source division 7.

A combination of the light source gas 62 with the reactive gas contained in the processing gas 61 will now be described. FIG. 5 shows a plasma emission spectrum of N₂ gas, with the ordinate axis representing emission intensity and the abscissa axis representing emission wavelength. As shown in FIG. 5, an appreciable level of emission occurs in the wavelength range of 300 nm to 400 nm, whereas no appreciable emission occurs at a wavelength of less than 290 nm.

When N₂ gas is used as the light source gas 62 and O₂ gas is used as the reactive gas for the processing gas 61, the O₂ gas dissociates into ions or radicals when it is irradiated with light having a wavelength of 242 nm or less, which corresponds to the absorption edge wavelength of O₂ gas. However, as described above, no appreciable emission occurs at a wavelength of less than 290 nm in the plasma emission of N₂ gas; therefore, dissociation of the O₂ gas does not occur. Accordingly, dissociation of the reactive gas, and thus etching of the template 50, will not occur by merely applying the plasma light 31 to the processing division 6. As described above, the type of the light source gas 62 can be appropriately selected depending on the absorption edge wavelength of the reactive gas used for the processing gas 61. Thus, the emission wavelength of the light source gas 62 is preferably set to be longer than the absorption edge wavelength of the reactive gas contained in the processing gas 61.

Instead of selecting a particular light source gas 62 in view of the reactive gas to be used, another method for adjusting the wavelength of the plasma light 31 applied to the processing division 6 is to impart to the shield 40 a function as a filter that blocks light at wavelengths shorter than the absorption edge wavelength of the processing gas 61. This alternative method enables the use, as the light source gas 62, of a gas which has a plasma emission spectrum containing light whose wavelength is shorter than the absorption edge wavelength of the processing gas 61. The impartment of the filter function can be achieved by using, as the shield 40 a colored glass filter having a long-pass filter function, for example.

In this first embodiment, leveling is performed on the fine structures 56 shown in FIG. 3C. The processing uses light whose wavelength is longer than the absorption edge wavelength of the reactive gas used for the processing gas 61. More specifically, leveling is performed using near-field light generated from the plasma light 31, which has passed through the shield 40 and irradiates the template 50, in the vicinity of the surfaces of the fine structures 56.

Leveling according to this first embodiment, performed by using near-field light, will now be described. As shown in FIG. 3C, the fine structures 56, which are three-dimensional portions finer than the three-dimensional pattern, exist in the patterned surface 54 of the template 50 to be subjected to leveling according to this first embodiment. Near-field light is generated when the fine structures 56 are irradiated with light. The near-field light is localized such that it covers the surfaces of the fine structures 56. The near-field light can cause a so-called non-adiabatic photochemical reaction that directly excites molecules to a vibrational level. Therefore, even though dissociation of the reactive gas by the plasma light 31 does not occur, the near-field light generated at the surfaces of the fine structures 56 reacts with molecules of the reactive gas, and causes the gas molecules to dissociate into gas radicals.

In this first embodiment, as shown in FIG. 6A, the template 50 is irradiated with the plasma light 31, whereby near-field light 32 is generated in the vicinity of the surfaces of the fine structures 56. The near-field light 32 is unlikely to be generated in flat portions of the surface of the template 50, and therefore the reactive gas is unlikely to dissociate near these flat portions. In contrast, the near-field light 32 is likely to be generated in the vicinity of the surfaces of the fine structures 56, and therefore the reactive gas is likely to dissociate in proximity to these fine structures 56. Leveling by etching of the protruding fine structures 56 is effected by radicals generated by the dissociation of the reactive gas. The fine structures 56 become smaller with the progress of leveling and, at the time when the fine structures 56 have been almost entirely removed, the intensity of the near-field light 32 is so low that its contribution to the dissociation of the reactive gas is negligible. The leveling by etching of the fine structures 56 is thus completed as shown in FIG. 6B with a substantial reduction in the size of protruding fine features 56. During the leveling process, the temperature of the stage 11 may be adjusted by the heater 12. For example, the efficiency of etching can be increased by appropriately raising the temperature of the stage 11 using the heater 12 to adjust the temperature to be in a range of room temperature to 80° C.

After the completion of leveling, the gate valve 16 of the processing apparatus 1 is opened, and the template 50 is detached from the stage 11 and then carried out of the chamber 10. Thereafter, the gate valve 16 is closed. The template 50 can now be used, for example, in imprinting.

According to the processing apparatus 1 and the above-described processing method of this embodiment, it is possible to perform leveling of a processing object while preventing etching of the processing object that would be caused by ions or radicals generated along with a plasma. In the case of a leveling technique which utilizes near-field light and uses laser as a light source, it is necessary to provide a laser light source having a desired wavelength appropriate to the reactive gas used. However, according to the leveling technique of this embodiment, which utilizes near-field light and uses plasma light as a light source, leveling processes using different reactive gases can be performed within the same apparatus simply by changing the light source gas 62.

### Second Embodiment

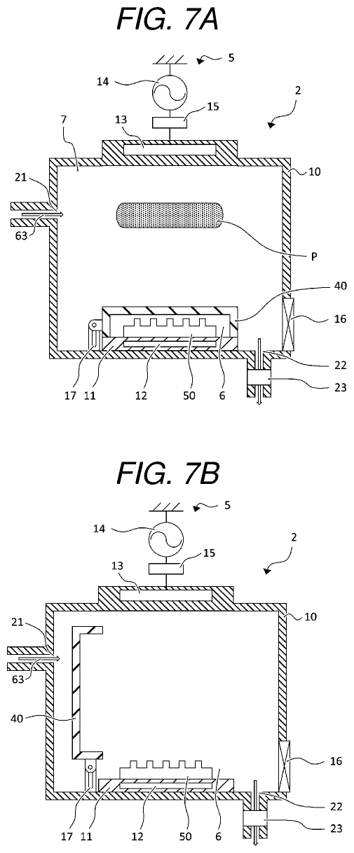

A processing apparatus and a processing method according to a second embodiment will now be described with reference to FIGS. 7A and 7B. FIGS. 7A and 7B are cross-sectional views showing the configuration of the processing apparatus according to the second embodiment.

The processing apparatus 2 according to the second embodiment differs from the first embodiment in that the shield 40 is connected to a moving section 17 so that the shield 40 can be moved between the position shown in FIG. 7A, where the shield 40 separates the processing division 6 from the light source division 7, and the position shown in FIG. 7B, where the shield 40 does not separate the processing division 6 from the light source division 7. The moving section 17 is depicted in this example as a hinge structure, but is not limited thereto. The second embodiment also differs in that the gas introduction port 21, the gas discharge portion 22 and the pressure regulator 23 are each provided singly. The processing method according to the second embodiment further differs from the first embodiment in that when carrying the template 50 into or out of the chamber 10, the shield 40 needs to be moved to the position where it does not separate the processing division 6 from the light source division 7. Also, a mixed gas 63 comprising a processing gas and a light source gas is introduced into the chamber 10.

A method for processing the template 50 using the processing apparatus 2 will now be described with reference to FIGS. 7A and 7B.

First, the template 50 is placed on the stage 11 in the chamber 10. The shield 40 is in the position shown in FIG. 7B, where the shield 40 does not separate the processing division 6 from the light source division 7. The position may be any position at which the shield 40 does not separate the processing division 6 from the light source division 7 and does not interfere with carrying-in/carrying-out of the template 50.

After the gate valve 16 is closed, the mixed gas 63 is introduced from the gas introduction port 21 into the chamber 10. When a mixed gas of N₂ (light source gas) and O₂ (reactive gas), for example, is used, the ratio of the O₂ gas to the N₂ gas may be 20% to 80%, preferably about 50%. The pressure in the chamber 10 may be adjusted to about 0.1 Pa to about 100 Pa.

Thereafter, the shield 40 is moved to the position shown in FIG. 7A, where the shield 40 separates the processing division 6 from the light source division 7, to carry out leveling of the template 50. The fine structures 56 of the template 50 can be leveled due to the presence of the mixed gas containing the processing gas between the template 50 and the shield 40.

After the completion of leveling, the shield 40 is moved to the position shown in FIG. 7B, and the template 50 is carried out of the chamber 10.

The processing apparatus 2 and the above-described processing method of this second embodiment can achieve the same effects as the first embodiment. Additionally, plasma etching processes may be performed simply by moving the shield 40 of the processing apparatus 2 to a position where it does not interfere.

### Third Embodiment

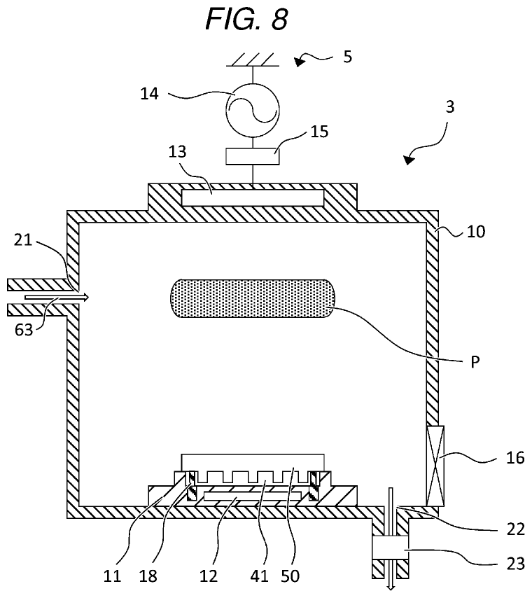

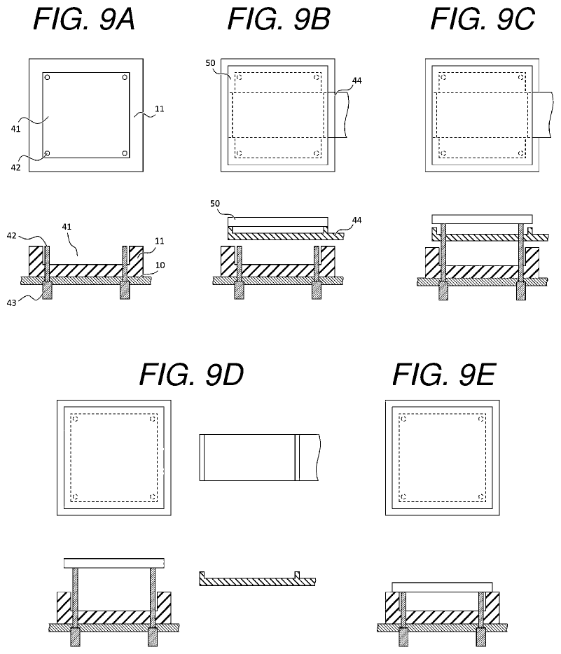

A processing apparatus and a processing method according to a third embodiment will now be described with reference to FIGS. 8 and 9A to 9E. FIG. 8 is a cross-sectional view showing the configuration of the processing apparatus 3 according to the third embodiment. FIGS. 9A through 9E are top views and cross-sectional views illustrating a method for carrying the template 50 into the processing apparatus 3. The processing apparatus 3 according to the third embodiment differs from the second embodiment in that the shield 40 and the moving section 17 are absent. Instead, a space 41, which is smaller in dimension than the template 50 but larger than the elevated portion 53, is provided in the stage 11. Lifts 18 for lifting the template 50 are provided in the space 41. The space 41 has a size sufficient to fit the three-dimensional pattern formed in the substrate placed on the stage 11. The processing method according to the third embodiment differs from the second embodiment in that the template 50 is placed upside down on the stage 11 (that is, the main surface 52 faces towards the stage 11 and thus a back side of the template 50 faces away from the stage 11).

A method for processing the template 50 using the processing apparatus 3 will now be described. First, the template 50 is carried upside down to the stage 11 in the chamber 10 by the conveyance arm 44, as shown in FIG. 9B.

The carry-in process will be described with reference to FIGS. 9A through 9E. The lifts 18 each include a lift pin 42 and an air cylinder 43. The air cylinder 43 vertically moves the lift pin 42. The lift pin 42 moves the template 50 up and down. Before the template 50 is carried in, the lift pins 42 are in a lowered state as shown in FIG. 9A. The template 50 is carried in by the conveyance arm 44 while the lift pins 42 are in a lowered state, as shown in FIG. 9B. Thereafter, as shown in FIG. 9C, the lift pins 42 move upward and lift the template 50 from the conveyance arm 44. Subsequently, as shown in FIG. 9D, the conveyance arm 44 is withdrawn from under the template 50. The conveyance arm 44 moves out of the chamber 10, and then the gate valve 16 is closed. After the gate valve 16 is closed, the mixed gas 63 is introduced into the chamber 10. When the mixed gas 63 is introduced into the chamber 10, the template 50 is still in a raised state, as shown in FIG. 9D. Accordingly, the mixed gas 63 is also introduced into the space 41 (located below the template 50) at this time. After the introduction of the mixed gas 63, the lift pins 42 are lowered and the template 50 is placed on the stage 11, as shown in FIG. 9E. As a result, as shown in FIGS. 8 and 9E, the space 41 is isolated by the combination of the template 50 and the stage 11. Thus, the for the reversed template 50, the substrate 51 itself performs substantially the same function as the shield 40 in the previous embodiments.

After lowering the template 50, leveling of the template 50 is performed. After the completion of leveling, the template 50 is carried out of the chamber 10. The carrying-out of the template 50 is performed by reversing the carry-in process (excepting for the introduction of the mixed gas 63, which is not carried out in the carrying-out process).

According to the processing apparatus 3 and the above-described processing method of this third embodiment, the substrate 51 itself of a reverse facing template 50 performs the same function as the shield 40. Therefore, the same effects as the first embodiment can be achieved. Furthermore, by just reversing the facing direction of the template 50 placed on the stage 11, the processing apparatus 3 can also be used to perform plasma etching, as in the second embodiment.

### Fourth Embodiment

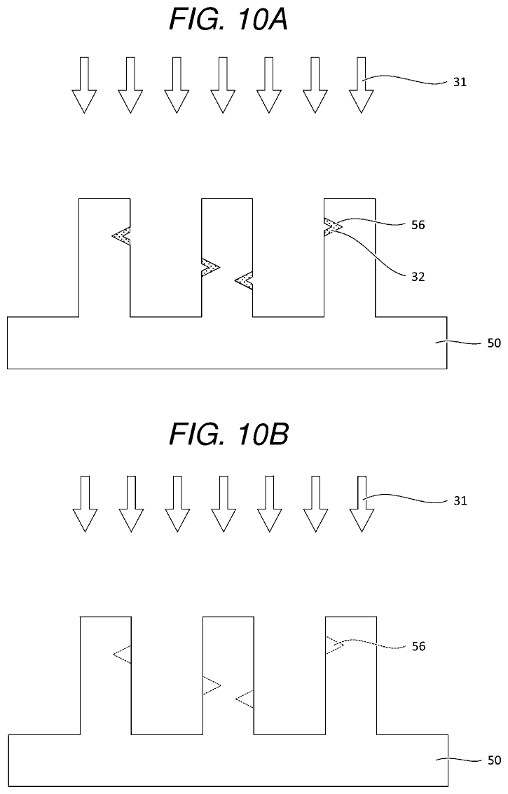

A processing method according to a fourth embodiment will now be described with reference to FIGS. 10A and 10B. FIGS. 10A and 10B are diagrams illustrating a method for processing the template 50 in the processing division 6 according to this embodiment. The processing method according to the fourth embodiment is performed using the processing apparatus 1 as in the first embodiment. This fourth embodiment differs from the first embodiment in that instead of the reactive gas, another gas (deposition gas) is used for the processing gas 61. The fourth embodiment is otherwise the same as the first embodiment. The use of another gas for the processing gas 61 makes it possible to deposit a material in recessed portions of the fine structures 56 of the template 50. Examples of gases which can be used in this context include methane (CH₄), propylene (C₃H₆), carbon tetrafluoride (CF₄), fluoroform (CHF₃), hexafluoroethane (C₂F₆), hexafluoro-1,3-butadiene (C₄F₆), octafluorocyclobutane (C₄F₈), silane (SiH₄), disilane (Si₂H₆), dichlorosilane (SiH₂Cl₂), trichlorosilane (SiHCl₃), and silicon tetrachloride (SiCl₄). By controlling a bias voltage, applied to the electrode upon the generation of a plasma, and the density of the plasma, both etching and deposition can be performed. Thus, depending on the applied bias voltage, CF₄, CHF₃, C₄F₆ and C₄F₈ may be used both as a reactive gas and as a deposition gas.

In the processing method of this fourth embodiment, the template 50 is irradiated with plasma light 31, as shown in FIGS. 10A and 10B, whereby near-field light 32 is generated in the vicinity of the surfaces of the fine structures 56 of the template 50. The energy of the plasma light 31 is less than the dissociation energy of the deposition gas. Furthermore, the near-field light 32 is unlikely to be generated in flat (non-recessed) portions of the surface of the template 50, and therefore the deposition gas is unlikely to react (be deposited) on these flat portions. In contrast, the near-field light 32 is likely to be generated in the vicinity of the surfaces of the fine structures 56, and therefore the deposition gas is likely to react and be deposited. Leveling of the fine structures 56 is provided through deposition of the material produced by the reaction of the deposition gas. The fine structures 56 thus become smaller with the progress of leveling. At the time when the fine structures 56 have been almost entirely removed, the intensity of the near-field light 32 will be so low that its contribution to the reaction of the deposition gas will be negligible. The leveling of the fine structures 56 (more particularly, those fine structures 56 which comprise recesses) through deposition is thus completed.

According to the processing apparatus 1 and above-described processing method of this fourth embodiment, it is possible to perform leveling of a processing object while preventing etching of the processing object that would otherwise be caused by ions or radicals generated along with a plasma. In the case of a leveling technique which utilizes near-field light and uses laser as a light source, it is necessary to provide a laser light source having a desired wavelength appropriate to the deposition gas used. However, according to the leveling technique of this fourth embodiment, which utilizes near-field light and uses plasma light as a light source, leveling processes using different deposition gases can be performed within the same apparatus simply by changing the light source gas 62.

### Fifth Embodiment

A processing method according to a fifth embodiment will now be described. The processing method according to the fifth embodiment is performed using the processing apparatus 2 as in the second embodiment. This fifth embodiment differs from the second embodiment in that instead of the reactive gas, a deposition gas is used for the processing gas 61 in the processing. This embodiment is otherwise the same as the second embodiment.

The processing apparatus 2 and processing method of this fifth embodiment can achieve the same effect as the fourth embodiment. Plasma etching can also be performed by moving the shield 40 of the processing apparatus 2 to a position where it does not interfere between the electrode 13 and the template 50.

### Sixth Embodiment

A processing method according to a sixth embodiment will now be described. The processing method according to the sixth embodiment is performed using the processing apparatus 3 as in the third embodiment. This sixth embodiment differs from the third embodiment in that instead of the reactive gas, a deposition gas is used for the processing gas 61 in the processing. This sixth embodiment is otherwise the same as the third embodiment.

The processing method of this sixth embodiment can achieve the same effects as the fourth embodiment. Furthermore, by reversing the direction of the template 50 placed on the stage 11, the processing apparatus 3 can also perform plasma etching, as in the second embodiment.

While certain embodiments have been described, these embodiments have been presented by way of example only, and are not intended to limit the scope of the present disclosure. Indeed, the novel embodiments described herein maybe embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A processing apparatus, comprising:
a chamber;
a first gas introduction port that introduces a first gas into the chamber;
a first gas discharge port that discharges the first gas from the chamber;
a stage that supports a processing object in the chamber;
a plasma generating section having an electrode and configured to generate a plasma in the chamber; and
a shield at a first position between the plasma generating section and the stage, the shield being light transmissive.

2. The processing apparatus according to claim 1, wherein the plasma generating section further comprises a power source and a matching box.

3. The processing apparatus according to claim 1, further comprising:
a second gas introduction port that introduces a second gas into the chamber; and
a second gas discharge port that discharges the second gas from the chamber, wherein
the shield divides the chamber into a first space and a second space,
the first gas introduction port and the first gas discharge port are connected to the first space, and
the second gas introduction port and the second gas discharge port are connected to the second space.

4. The processing apparatus according to claim 1, wherein the shield is moveable from the first position to a second position not between the plasma generating section and the stage.

5. The processing apparatus according to claim 1, wherein the shield is a glass.

6. The processing apparatus according to claim 1, wherein the shield filters light with wavelengths is longer than a predetermined absorption edge wavelength of a gas introduced into the chamber.

7. The processing apparatus according to claim 1, wherein the shield is one of glass, sapphire, calcium fluoride, magnesium fluoride, polycarbonate, or an acrylic resin.

8. The processing apparatus according to claim 1, further comprising:
a heater configured to heat the processing object on the stage.

9. The processing apparatus according to claim 1, further comprising:
a moving section connected to the shield, wherein
the moving section is configured to move the shield from the first position to a second position that is not between the plasma generating section and the stage.

10. The processing apparatus according to claim 9, wherein the moving section comprises a hinge.

11. A processing method, comprising:
placing a processing object in a chamber;
introducing a first gas into the chamber;
introducing a second gas into the chamber;
generating a plasma on a first side of a shield, the processing object being on a second side of the shield opposite the first side; and
exposing the processing object to at least the second gas and a wavelength of light generated by the plasma and passed through the shield.

12. The processing method according to claim 11, wherein the second gas is a reactive gas.

13. The processing method according to claim 11, wherein the second gas comprises at least one gas selected from oxygen (O₂), ozone (O₃), nitrous oxide (N₂O), carbon monoxide (CO), carbon dioxide (CO₂), fluorine (F₂), nitrogen trifluoride (NF₃), nitrogen tetrafluoride (NF₄), hexafluoro-1,3-butadiene (C₄F₆), octafluorocyclobutane (C₄F₈), fluoroform (CHF₃), difluoromethane (CH₂F₂), sulfur hexafluoride (SF₆), chlorine (Cl₂), boron trichloride (BCl₃), hydrogen chloride (HCl), or hydrogen bromide (HBr).

14. The processing method according to claim 11, wherein the second gas is a deposition gas.

15. The processing method according to claim 11, wherein the second gas comprises at least one gas selected from methane (CH₄), propylene (C₃H₆), carbon tetrafluoride (CF₄), fluoroform (CHF₃), hexafluoroethane (C₂F₆), hexafluoro-1,3-butadiene (C₄F₆), octafluorocyclobutane (C₄F₈), silane (SiH₄), disilane (Si₂H₆), dichlorosilane (SiH₂Cl₂), trichlorosilane (SiHCl₃), or silicon tetrachloride (SiCl₄).

16. The processing method according to claim 11, wherein the first and second gas are introduced into the chamber as a mixed gas comprising the first and second gases.

17. The processing method according to claim 11, further comprising:
adjusting the temperature of the processing object while exposing the processing object to at least the second gas and the wavelength of light generated by the plasma.

18. The processing method according to claim 11, further comprising:
positioning the shield between the processing object and an electrode of a plasma generating section that generates the plasma in the chamber.

19. The processing method according to claim 11, wherein the processing object is an imprint template.

20. A processing method, comprising:
placing a processing object having a patterned surface on a stage in a chamber with the patterned surface facing toward the stage;
introducing a mixed gas into the chamber, the mixed gas comprising a light source gas and a reactive gas or a deposition gas;
sealing a space formed by the processing object and the stage;
generating a plasma outside of the sealed space; and
exposing the patterned surface to a wavelength of light generated by the plasma and passed through the processing object.
